(19) United States
(12) Patent Application Publication
(10) Pub. No.: US 2005/0212017 A1
(43) Pub. Date: Sep. 29, 2005

(54) Vehicle actuated gate apparatus

(76) Inventor: Eugene Heisserer, Chaffee, MO (US)

Correspondence Address: POLSTER, LIEDER, WOODRUFF & LUCCHESI, 12412 POWERSCOURT DRIVE SUITE 200, ST. LOUIS, MO, 63131-3615, US

(21) Appl. No.: 11/092,359

(22) Filed: Mar. 29, 2005

Related U.S. Application Data
(60) Provisional application No. 60/557,173, filed on Mar. 29, 2004.

(51) Int. Cl. H01L 29/80; H01L 21/00

(52) U.S. Cl. 257/257; 438/48

(57) ABSTRACT

A vehicle-actuated gate system having a gate assembly with a gate member pivotally attached to a main post. A vehicle engages the gate member to pivot the gate member between an open and closed position where it is secured with an engagement member having at least one inclined surface and a detent for securing a bottom edge of the gate member.

### CROSS-REFERENCE TO RELATED APPLICATIONS

This application is related to U.S. Provisional Patent Application No. 60/557,173 filed Mar. 29, 2004 from which priority is claimed, and is hereby incorporated by reference.

### STATEMENT REGARDING FEDERALLY SPONSORED RESEARCH

Not Applicable.

### BACKGROUND OF THE INVENTION

In general, farm fence gates are designed to open and close manually. However, manual gates are very inconvenient in high traffic areas used by farm vehicles because the operator must get off and on the vehicle to open and close the gate. As a result, there have been many attempts to design a gate that avoids this inconvenience. Some designs are automated gates and others are remotely actuated. However, all of these previous designs are complicated, cumbersome and expensive. As a result, none of these previous designs have achieved much commercial success.

Therefore, there is a long felt need for a simple and inexpensive system that will allow an operator to open and close a gate without leaving his or her vehicle.

### DESCRIPTION OF THE DRAWINGS

In the accompanying drawings which form part of the specification:

FIG. 1 is perspective view of a vehicle-actuated gate system.

FIG. 2 is a side view of a first engagement member.

FIG. 3 is a side view of a second engagement member.

FIG. 4 is an alternate embodiment of the vehicle-actuated gate system.

Corresponding reference numerals indicate corresponding parts throughout the several figures of the drawings.

### DETAILED DESCRIPTION

The following detailed description illustrates the invention by way of example and not by way of limitation. The description clearly enables one skilled in the art to make and use the invention, describes several embodiments, adaptations, variations, alternatives, and uses of the invention, including what is presently believed to be the best mode of carrying out the invention.

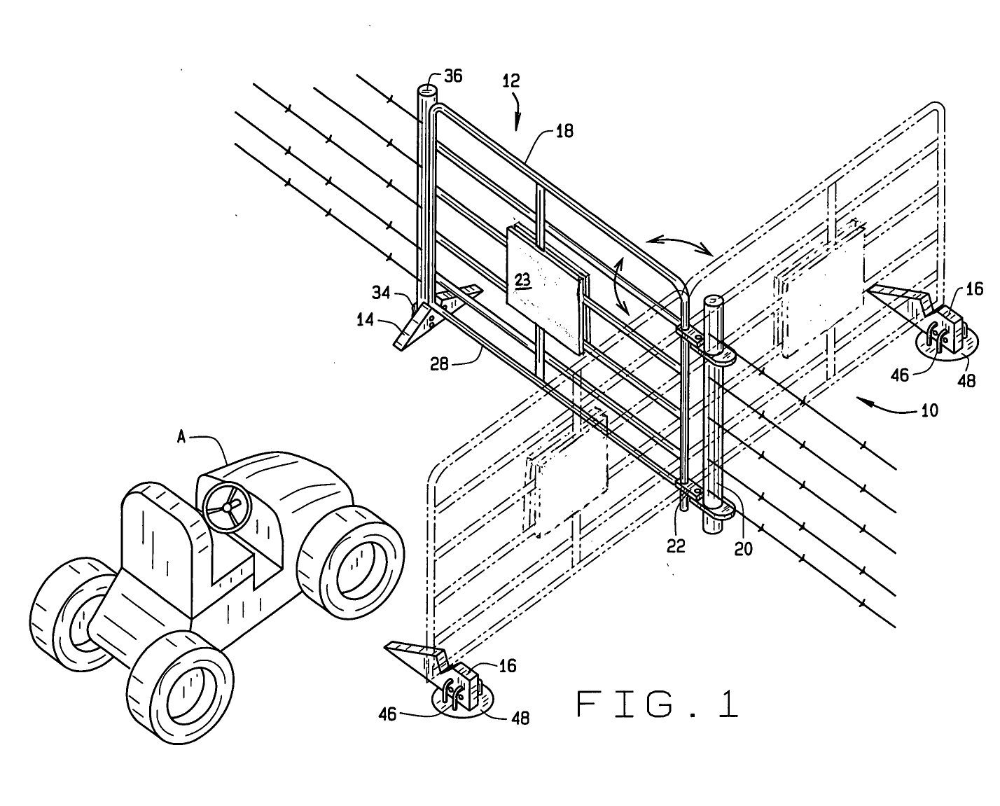

FIG. 1 illustrates a preferred embodiment of the present invention, which is generally referred to as a vehicle-actuated gate system 10. The vehicle-actuated gate system 10 includes a gate assembly 12 that operatively engages with first and second engagement members 14 and 16 so that the gate assembly 12 moves between an open position and a closed position.

The gate assembly 12 includes gate member 18 pivotally attached to a main post 20 with hinges 22, which allow the gate member 18 to open and close in either direction. There is “play” or “slack” in the hinged connection between the gate member 18 and the main post 20 that allows slight vertical movement in the gate member 18. This vertical movement allows the gate member 18 to engage and disengage with the engagement members 14 and 16 as described below. The gate assembly also includes a bump plate 23 attached to the gate member 18, as by welding, to prevent damage to the gate member 18 when the vehicle bumps against it. The embodiment of FIG. 1 shows a typical tube type gate, which are well known in the art. However, other types of gates can also be used, such as, wood, channel, or wire type gate.

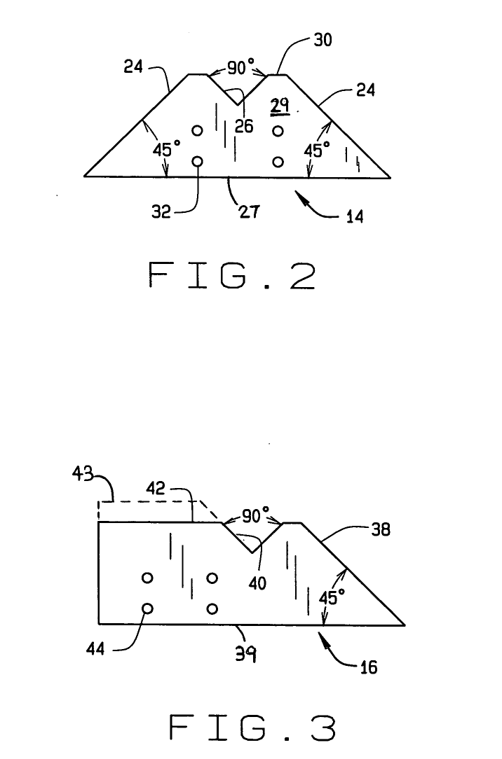

As shown in FIGS. 1 and 2, the first engagement member 14 is a rectangular block having an inclined surface 24 at each end for bi-directional opening of the gate member 18. In addition, the first engagement member 14 includes a detent 26 positioned between the inclined surfaces 24 for securing a bottom edge 28 of the gate member 18 in a closed position. Each inclined surface 24 slopes downwardly and faces away from the detent 26 at an angle preferably between about 20°-60° relative to a bottom surface 27 of the engagement member 14 to allow the bottom edge 28 to easily slide over the inclined surfaces 24 and secure within the detent 26. When the gate member 18 pivots towards the closed position, the inclined surfaces 24 move the gate member 18 vertically upwards as a result of the slack in the hinges 22. When the gate member 18 reaches the detent 26, the gate member 18 moves vertically downwards due to its own weight, thereby wedging the bottom edge 28 of the gate member 18 into the detent 26.

As the angle of the inclined surfaces 24 increase, the force needed to slide the gate member 18 up the inclined surfaces 24 and into the detent 26 increases. Larger angles may be desirable for operation with larger vehicles so that the vehicle A does not tend to over-pivot the gate member 18 during operation. Therefore, the angle of the inclined surfaces 24 is selected to achieve a desired engagement force corresponding to vehicle size. In FIGS. 1 and 2, the first engagement member 14 has inclined surfaces 24 with an angle of about 45°, which works well with most farm vehicles.

The detent 26 is preferably V-shaped with an acute angle preferably between about 60°-120°, which allows the detent 26 to engage a variety of different shapes and sizes of the bottom edge 28 of the gate member 18. As the gate member 18 pivots, flats 30 on the top surface aid the transition between the detent 26 and the inclined surfaces 24. Selecting the angle of the detent 26 is a balance between how easily the gate member disengages the first engagement member 14 and how secure the gate member 18 is within the detent 26. As the angle of the detent 26 increases, the gate member 18 becomes more secure in the detent 26, but the force needed to slide the gate member 18 out of the detent 26 increases, thus, making disengagement more difficult. Oppositely, as the angle of the detent 26 decreases, the gate member 18 becomes less secure in the detent 26, but the force needed to slide the gate member 18 out of the detent 26 increases, thus, making disengagement easier. Therefore, a steeper angle is desired for applications where larger winds or larger animals are present, while a more gradual angle is desired for applications where smaller or no winds or smaller or no animals are present. In FIGS. 1 and 2, the first engagement member 14 has a detent with an angle of about 90°, which works well for most applications.

Those skilled in the art will recognize that any multitude of angles can be used for the inclined surfaces 24. In addition, any suitable size and shape of detent 26 can be used to correspond to the size and shape of the bottom edge 28 of the gate member 18.

The engagement member 14 includes mounting holes 32 with corresponding fasteners 34, such as lag bolts, to secure the first engagement member 14 to a secondary post 36 of the gate assembly 12. For proper installation, the first engagement member 14 is positioned with two parallel side surfaces 29 perpendicular to the plane of the gate member 18 when the gate member 18 is in the closed position. In an alternative embodiment, the engagement member 14 can be secured to the ground with an appropriate means, such as a concrete pad.

As shown in FIGS. 1 and 3, the second engagement member 16 is a rectangular block having an inclined surface 38 at one end and a flat surface 42 at the opposite end. A detent 40 is located between the inclined surface 38 and the flat surface 42 for securing a bottom edge 28 of the gate member 18 in an open position. The flat surface 42 prevents the gate member 18 from pivoting past the detent 40, thereby making the second engagement member 16 unidirectional. In an alternate embodiment, the second engagement member 16 has a raised flat surface 43, illustrated by the dotted line in FIG. 3. The raised flat surface 43 provides further prevention against the gate member 18 pivoting past the detent 40.

Similar to the first engagement member 14, the inclined surface 38 of the second engagement member 16 is preferably between an angle of 20°-60° relative to a substantially flat bottom surface 39 of the engagement member 16 to allow the bottom edge 28 of the gate member 18 to easily slide over the inclined surface 38 and into the detent 40. The detent 40 is preferably triangular-shaped with an acute angle preferably between about 60°-120°, which allows the detent 40 to engage a variety of different shapes and sizes of bottom edge. As shown in FIG. 3, the second engagement member 14 has inclined surface 38 with an angle of about 45° and a detent 40 with an angle of about 90°. However, those skilled in the art will recognize that any multitude of angles can be used for the inclined surface 38. In addition, any suitable size and shape of detent 40 can be used to correspond to the size and shape of the bottom edge 28 of the gate member 18.

The second engagement members 16 include mounting holes 32 with corresponding fasteners 34, such as lag bolts, to secure the second engagement member 16 to a concrete pad 48. In an alternative embodiment, the engagement member 14 can be secured to the ground with other appropriate means, such as post. For proper installation, the second engagement member 16 is positioned at a preferably 90° angle along the pivot path of the gate member 18 with the inclined surface 38 parallel to the gate assembly 12 and facing the direction that the gate assembly 12 closes. However, those skilled in the art will recognize that the second engagement members 16 can be positioned at other angles along the pivot path of the gate member 18. In the preferred embodiment, an engagement member 16 is located on both sides of the gate assembly 12 to secure the gate member 18 when opened in either direction.

In operation, the gate assembly 12 starts with the gate member 18 positioned in the closed position, where the bottom edge 18 is secured in the detent 26 of the first engagement member 14. An operator in a vehicle A approaches the gate assembly 12 from either direction. The operator bumps the vehicle A against the bump plate 23 of the gate member 18 to disengage it from the first engagement member 14, thereby sliding the bottom edge 28 of the gate member 18 out of the detent 26 and down the inclined surface 24. Using the vehicle A, the operator pivots the gate member 18 until it slides up the inclined surface 38 of the second engagement member 16 and into the detent 40, thereby securing the gate member 18 in the open position without the operator ever leaving the vehicle A.

To close the gate assembly 12, the operator bumps the vehicle A against the bump plate 23 of the gate member 18 to disengage it from the second engagement member 16, thereby sliding the bottom edge 28 of the gate member 18 out of the detent 40 and down the inclined surface 38. Using the vehicle A, the operator pivots the gate member 18 until it slides up the inclined surface 24 of the first engagement member 16 and into the detent 26, thereby securing the gate member 18 in the closed position without the operator ever leaving the vehicle A.

It is important to note that the engagement members 14 and 16 can be made from any suitable material, such as plastic, wood, or metal. However, the material selected should be cost efficient and have characteristics that provide a long useful life in outdoor applications. In the present embodiment, the engagement members 14 and 16 are preferably made from plastic because of its resistance to outdoor elements and its low cost.

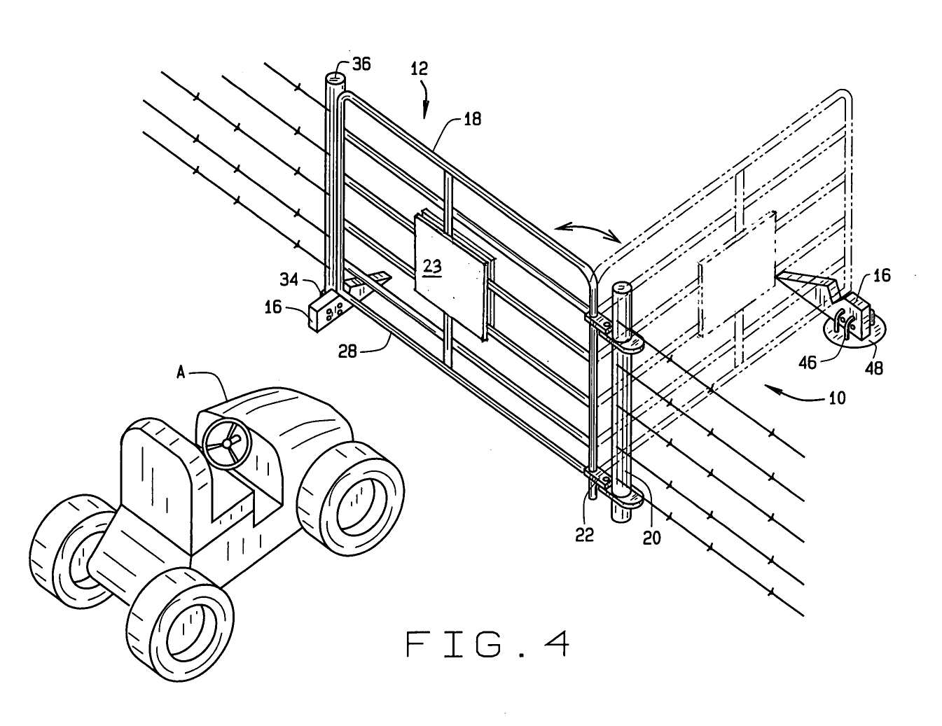

Other embodiments of the vehicle-actuated gate system 10 can use alternate arrangements of the engagement members 14 and 16. For example, the gate system 10 can use two of the second engagement members 16, as shown in FIG. 4. In this alternate embodiment, one of the second engagement members 16 replaces the first engagement member 14 as shown in FIG. 1. In this arrangement, the gate member 28 only opens in one direction, rather than both directions.

In another embodiment (not shown), one of the engagement members 14 or 16 is used to secure the gate member 18 in the closed position, but no engagement member is used to secure the gate member 18 in the open position.

In yet another embodiment (not shown), the first engagement member 14 is positioned in the same place as FIG. 1, but the second engagement members 16 are placed at a different angle along the pivot path of the gate member 18, such as at an angle of 120°. Those skilled in the art will recognize that the second engagement members can be positioned anywhere along the pivot path of the gate member 18.

Various accessories can be used along with the vehicle-actuated gate system 10 as described above. For example, a latching means or lock (not shown) may be used to further secure the gate assembly 12 in the closed position.

Changes can be made in the above constructions without departing from the scope of the invention, it is intended that all matter contained in the above description or shown in the accompanying drawings shall be interpreted as illustrative and not in a limiting sense.

1. A vehicle-actuated gate system, comprising:
a gate assembly having a gate member pivotally attached to a main post, wherein the gate member pivots between an open and closed position;
a first engagement member having at least one inclined surface and a detent for securing a bottom edge of the gate member in the closed position so that a vehicle can engage the gate member to pivot the gate assembly between an open position and a closed position.

2. The vehicle-actuated gate system of claim 1, further comprising:
a second engagement member having an inclined surface and a detent for securing a bottom edge of the gate member in the open position.

3. The vehicle-actuated gate system of claim 1, wherein the first engagement member includes two inclined surfaces for bi-directional opening of the gate member to a first open position or a second open position.

4. The vehicle-actuated gate system of claim 3, further comprising:
a second engagement member having an inclined surface and a detent for securing a bottom edge of the gate member in the first open position;
a third engagement member having an inclined surface and a detent for securing a bottom edge of the gate member in the second open position.

5. The vehicle-actuated gate system of claim 1, wherein the first engagement member is mounted to the main post.

6. The vehicle-actuated gate system of claim 1, wherein at least one inclined surface is at an angle between about 20°-60°.

7. The vehicle-actuated gate system of claim 1, wherein the detent is V-shaped with an angle between about 60°-120°.

8. The vehicle-actuated gate system of claim 2, wherein the inclined surface of the second engagement member is at an angle between about 20°-60°.

9. The vehicle-actuated gate system of claim 2, wherein the detent of the second engagement member is V-shaped with an angle between about 60°-120°.

10. The vehicle-actuated gate system of claim 4, wherein the inclined surface of the second engagement member is at an angle between about 20°-60°; and
wherein the inclined surface of the third engagement member is at an angle between about 20°-60°.

11. The vehicle-actuated gate system of claim 4, wherein the detent of the second engagement member is V-shaped with an angle between about 60°-120°; and
wherein the detent of the third engagement member is V-shaped with an angle between about 60°-120°.

12. An engagement member for a vehicle-actuated gate system, comprising:
at least one inclined surface;
a detent for securing a bottom edge of a gate member in a closed so that a vehicle can engage the gate member to pivot the gate member between the closed position and an open position.

13. The engagement member of claim 12, further comprising two inclined surfaces for bi-directional opening of the gate member to a first open position or a second open position.

14. The vehicle-actuated gate system of claim 12, wherein the first engagement member is mounted to a main post.

15. The vehicle-actuated gate system of claim 12, wherein at least one inclined surface is at an angle between about 20°-60°.

16. The vehicle-actuated gate system of claim 12, wherein the detent is V-shaped with an angle between about 60°-120°.

17. A method of operating a vehicle-actuated gate system, the gate system having a gate member pivotally attached to a main post, wherein the gate member pivots between an open and closed position, comprising the steps of:
providing a first engagement member having at least one inclined surface and a detent for securing a bottom edge of the gate member in the closed position;
engaging the gate member with a vehicle;
disengaging the gate member from the first engagement member by using the vehicle;
pivoting the gate member from the closed position to the open position by using the vehicle; and
wherein an operator of the vehicle never leaves the vehicle during the operation of the vehicle-actuated gate system.

18. The method of claim 17, further comprising the steps of:
engaging the gate member with a second engagement member by using the vehicle to secure the gate member in the open position.

19. The method of claim 18, further comprising the steps of:
disengaging the gate member from the second engagement member by using the vehicle;
pivoting the gate member from the closed position to the open position by using the vehicle; and
engaging the gate member with the first engagement member by using the vehicle to secure the gate member in the closed position.
